(19) United States
(12) Patent Application Publication
(10) Pub. No.: US 2008/0268629 A1
(43) Pub. Date: Oct. 30, 2008

(54) Method of Forming Overlay Mark of Semiconductor Device

(75) Inventor: Sung Min Jun, Busan (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-Si (KR)

(21) Appl. No.: 12/057,095

(22) Filed: Mar. 27, 2008

(30) Foreign Application Priority Data
Apr. 25, 2007 (KR) KR 2007-040416

(51) Int. Cl. H01L 21/71

(52) U.S. Cl. 438/584; 257/E21.536

(57) ABSTRACT

A method of fabricating a semiconductor device wherein, in forming an overlay mark in a scribe line region between dies in a mask process, a semiconductor substrate is provided in which a contact plug is formed in a contact hole of a dielectric layer in the scribe line region and a trench is formed on the contact plug. A first metal layer for a metal line is formed in the contact plug and the dielectric layer through an ALD (Atomic Layer Deposition) method so that a step generated by the trench remains intact. A second metal layer for a metal line is formed on the first metal layer using a sputtering method so that the step remains intact.

### CROSS-REFERENCE TO RELATED APPLICATION

Priority to Korean patent application number 10-2007-040416, filed on Apr. 25, 2007, the entire disclosure of which is incorporated by reference in its entirety, is hereby claimed.

### BACKGROUND OF THE INVENTION

The invention relates to a method of forming an overlay mark of a semiconductor device and, more particularly, to a method of forming an overlay mark of a semiconductor device, in which it can improve overlay measurement accuracy.

In fabricating semiconductor devices, overlay measurement must be performed before an etch process is carried out after exposure and development processes are performed. Overlay measurement is an important process of determining whether it is possible to perform an etch process by measuring the degree of alignment between a previous layer pattern and a current layer pattern. There is a tendency that the importance of measurement accuracy continuously increases as a function of reduction in the design rule.

For overlay measurement, an overlay measurement apparatus (for example, KLA by KLA-Tencor Corporation or BIORAD by Bio-Rad Laboratories, Inc.) and a reference mark for measurement are generally necessary. In general, the mark is formed as a pattern of a specific form in a boundary region (i.e., a scribe line region) between dies.

In general, overlay error is more easily generated in exposure and development processes for forming a metal line using aluminum (Al) than in other exposure and development processes, for reasons that follow.

First, the grain size of aluminum (Al) is large in the aluminum (Al) formation process of forming a metal line. Thus, aluminum (Al) is deposited asymmetrically in an overlay box having a different shape from that of a cell.

Second, not only is error generated, but also alignment is not performed properly upon overlay measurement and analysis due to a unique characteristic of an overlay measurement apparatus.

Third, a sputtering method causing directional growth is employed at the time of the aluminum (Al) formation process. Hence, a die size becomes larger or smaller than a desired size at the time of an exposure process, resulting in improper alignment. Due to this, overlay error is generated. This is described below with reference to FIG. 1.

Referring to FIG. 1, in a wafer 100, A designates a die size to be exposed at the time of an exposure process and B designates a die size at the time of the exposure process. If aluminum (Al) is formed using a sputtering method, the exposed die size becomes larger than the die size A that should have been originally exposed at the time of the exposure process.

Fourth, an electromagnetic field rotated within a tool in which the sputtering method is performed is used in the aluminum (Al) formation process. This field rotates the wafer slightly, resulting in improper alignment. Consequently, overlay error occurs. This is described below with reference to FIG. 2.

Referring to FIG. 2, in a wafer 200, C designates a die size to be exposed at the time of an exposure process and D designates a die size within the wafer 200 rotated at the time of the exposure process. If aluminum (Al) is formed using an electromagnetic field rotated within a tool in which a sputtering method is performed, the wafer is rotated slightly. Hence, the location of the desired die size C when exposure is originally performed becomes different from that of the die D within the rotated wafer 200.

### BRIEF SUMMARY OF THE INVENTION

The invention is directed to a method of forming an overlay mark of a semiconductor device, in which a metal, preferably aluminum (Al), nucleus is created through an ALD (Atomic Layer Deposition) method with excellent step coverage, and wherein a metal, preferably aluminum (Al), layer is formed using a sputtering deposition method after the nucleation size is increased, so the step topology of metal (e.g., aluminum (Al)) is asymmetrically formed in a cell region and an overlay mark can be improved.

Accordingly, one aspect of the invention provides a method of forming an overlay mark of a semiconductor device in a scribe line region between dies in a mask process, including providing a semiconductor substrate comprising a contact plug formed in a contact hole of a dielectric layer in a scribe line region and a trench formed on the contact plug, said trench defining a step, forming a first metal layer for a metal line in the contact plug and the dielectric layer through an ALD (Atomic Layer Deposition) method so that the step remains intact, and forming a second metal layer for a metal line on the first metal layer using a sputtering method so that the step remains intact.

The first metal layer preferably comprises aluminum (Al), wherein a nucleus of the aluminum (Al) is created. The second metal layer preferably comprises aluminum (Al). The first metal layer and the second metal layer are preferably formed using different chambers.

### BRIEF DESCRIPTION OF THE DRAWINGS

FIG. 1 illustrates that a wafer size increases compared to a wafer size A that should have been originally exposed at the time of an exposure process by employing a sputtering method caused by the directional growth in an aluminum (Al) formation process;

FIG. 2 illustrates that a desired wafer size differs from the size of a wafer when exposure is performed since the wafer is rotated slightly using an electromagnetic field, which field is rotated within a tool in which a sputtering method is performed, in an aluminum (Al) formation process; and

FIG. 3 is a sectional view illustrating a method of forming an overlay mark of a semiconductor device according to an embodiment of the invention, and illustrates a process of forming metal in a region in which an overlay mark of a specific shape is formed within a scribe line region between dies simultaneously when a metal layer for forming a metal line is formed in the die.

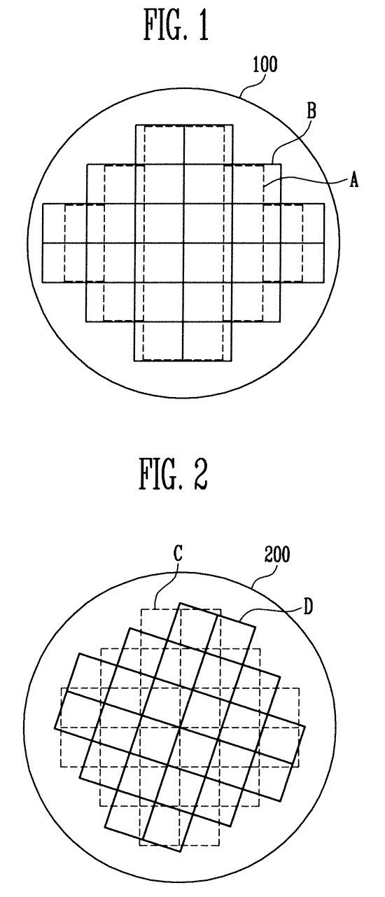

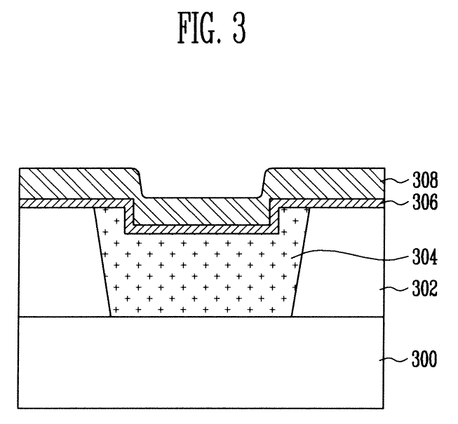

### DESCRIPTION OF SPECIFIC EMBODIMENTS

Now, a specific embodiment according to the invention will be described with reference to the accompanying drawings. However, the scope of the invention is not limited to the disclosed embodiment, but may be implemented in various manners. The embodiment is provided to complete the disclosure of the invention and to allow those having ordinary skill in the art to understand the scope of the invention. The scope of the invention is defined by the claims.

FIG. 3 is a sectional view illustrating a method of forming an overlay mark of a semiconductor device according to an embodiment of the invention. FIG. 3 illustrates a process of forming metal (illustratively and preferably aluminum (Al)) in a region in which an overlay mark of a specific shape is formed within a scribe line region between dies simultaneously when a metal, preferably aluminum (Al), layer for forming a metal line is formed in the die. The same process steps are performed on a die while the following process steps are performed on a scribe line region.

A dielectric layer 302 is formed on a semiconductor substrate 300. A contact hole is formed by selectively etching the dielectric layer 302. The dielectric layer 302 is preferably formed from an oxide, for example.

A first metal layer is formed within the contact hole so that the contact hole is gap filled. A CMP (Chemical Mechanical Polishing) process is then performed until a top surface of the dielectric layer 302 is exposed, thus forming a contact plug 304. Here, the first metal layer is preferably formed of tungsten (W). During the polishing process of forming the contact plug 304, a trench having a step is formed in some regions on the contact plug 304. The contact plug 304 functions to connect a lower region, and an upper region to be formed in a subsequent process.

A second metal layer 306, preferably comprising aluminum, is formed on the contact plug 304 and the dielectric layer 302. The second metal layer 306 preferably creates a metal (e.g., aluminum (Al)) nucleus using an ALD (Atomic Layer Deposition) method with excellent step coverage. A great deal of emphasis is placed on the formation process of the second metal layer 306 when compared with the existing formation process. In the formation process of the second metal layer 306, the step remains intact due to the trench formed on the contact plug 304. If the nucleation is increased as described, the step topology in a subsequent process can be improved.

A third metal layer 308 is formed on the second metal layer 306. The third metal layer 308 is illustratively and preferably formed of aluminum (Al) using a rapid sputtering deposition method. When the third metal layer 308 is formed, the step, which remains intact in the formation process of the second metal layer 306, remains intact. The second metal layer 306 and the third metal layer 308 are preferably formed using different chambers.

As described above, a metal, preferably aluminum (Al), nucleus is created through the ALD method with excellent step coverage, and a metal (preferably aluminum (Al)) layer (i.e., the third metal layer 308) is formed using a sputtering deposition method after the aluminum (Al) nucleus is increased in size. Thus, the step topology of the third metal layer 308 asymmetrically formed in the cell region and the overlay mark can be improved. By improving alignment accuracy as described above, the process yield of a device and reliability of a device operation can be improved.

As described above, the invention can have the following advantages.

First, an aluminum (Al) or other metal nucleus is created through an ALD method with excellent step coverage, wherein an aluminum (Al) or other metal layer (i.e., the third metal layer) is formed using a sputtering deposition method after the metal (e.g., aluminum (Al)) nucleus is increased in size. Thus, the step topology of the third metal layer asymmetrically formed in the cell region and the overlay mark can be improved.

Next, as alignment accuracy is increased, the process yield of a device and reliability of a device operation can be improved.

The embodiment disclosed herein has been proposed to allow a person skilled in the art to easily implement the invention, and the person skilled in the part may readily implement the invention, guided by the present disclosure. Therefore, the scope of the invention is not limited by or to the embodiment as described above, and should be construed to be defined only by the appended claims and their equivalents.

What is claimed is:

1. A method of forming an overlay mark of a semiconductor device in a scribe line region between dies in a mask process, the method comprising:
providing a semiconductor substrate comprising a contact plug formed in a contact hole of a dielectric layer in a scribe line region and a trench formed on the contact plug, with a step defined by said trench;
forming a first metal layer for a metal line in the contact plug and the dielectric layer through an ALD (Atomic Layer Deposition) method so that the step remains intact; and
forming a second metal layer for a metal line on the first metal layer using a sputtering method so that the step remains intact.

2. The method of claim 1, wherein the first metal layer comprises aluminum (Al), and comprising creating a nucleus of the aluminum (Al).

3. The method of claim 1, wherein the second metal layer comprises aluminum (Al).

4. The method of claim 1, comprising forming the first metal layer and the second metal layer using different chambers.
